(19) United States
(12) Patent Application Publication
(10) Pub. No.: US 2013/0020582 A1
(43) Pub. Date: Jan. 24, 2013

(54) RAPID FABRICATION METHODS FOR FORMING NITRIDE BASED SEMICONDUCTORS BASED ON FREESTANDING NITRIDE GROWTH SUBSTRATES

(71) Applicants: Scott M. Zimmerman, Basking Ridge, NJ (US); William R. Livesay, San Diego, CA (US); Richard L. Ross, Del Mar, CA (US)

(72) Inventors: Scott M. Zimmerman, Basking Ridge, NJ (US); William R. Livesay, San Diego, CA (US); Richard L. Ross, Del Mar, CA (US)

(21) Appl. No.: 13/555,076

(22) Filed: Jul. 20, 2012

Related U.S. Application Data
(60) Provisional application No. 61/572,768, filed on Jul. 21, 2011.

(51) Int. Cl. H01L 29/20

(52) U.S. Cl. 257/76; 257/E29.089

(57) ABSTRACT

High temperature bonding and interconnect methods can be used for LED and other optoelectronic devices based on freestanding nitride devices. Inorganic glasses, especially those which exhibit a CTE, which substantially matches the CTE of the freestanding nitride devices, can provide hermetic sealing of the freestanding nitride devices or the contact regions of the freestanding nitride devices. The freestanding nitride devices are typically freestanding nitride veneers.

### REFERENCE TO PRIOR APPLICATION

This application claims the benefit of U.S. Provisional Patent Application Ser. No. 61/572,768, which was filed on Jul. 21, 2011, which is herein incorporated by reference.

### BACKGROUND OF THE INVENTION

Light emitting diodes (LEDs) are typically fabricated using standard semiconductor packaging techniques. Die are mounted using epoxy or solder onto a submount, interconnect is via wirebonding or flip chip methods, and then organic encapsulants are formed over the assembly. While this approach is useful in low intensity applications, the cost and performance levels are insufficient for general lighting applications. Optoelectronics, electronics, solar, and sensors applications can also benefit from lower cost higher performance devices. The need therefore exists for novel fabrication methods, which reduce cost and enable electronic, optical, and optoelectronic applications.

Presently rapid thermal annealing creates ohmic contacts in nitride based devices. In this process various metals are deposited on p and n doped layers of the devices. Temperatures in excess of 650 degrees C. are then rapidly applied to the devices in the presence of a variety of atmospheric conditions. The resulting formation of conductive oxides and/or diffusion effects creates the ohmic contact. This contact formation, however, forms a very thin diffusion based layer which is susceptible to aging and environmental effects. The need therefore exists for more robust ohmic contacts to doped nitride layers. The thinness of the diffusional layers also limits what type of subsequent metal contacts can be used. This is unlike the solar cell industry in which thick film silver paste can be used rather than expensive vapor deposited metals as required in the LED industry. Vertical devices are preferred like the solar cell industry. The need however exists in the LED industry and nitride industry in general for economical methods of forming vertical nitride devices.

It is important to differentiate the freestanding nitride veneers disclosed in this invention from template and bulk nitride wafers. Templates are typically nitride layers grown on a non-native substrate, such as sapphire, SiC, silicon, or other single crystal substrates, with a reasonable lattice match to nitrides. In this case, device growth is done on a bimorph structure of two dissimilar materials. The lattice mismatch and the thermal expansion coefficient mismatches dictate that significant bow exists either during room temperature processing or growth processing. Bow at room temperature adversely affects yield for contact formation and liftoff processes. Bow at growth temperature leads to non-uniform device growth. As an example, a 2 inch 30 micron HVPE grown GaN template on sapphire can exhibit greater than 200 microns of bow at growth temperature if it is substantial flat at room temperature. This effect is even pronounced at thicker layers or larger diameter wafers. Excessive bow can also lead to wafer cracking which can lead to reactor damage.

The bimorph nature of a template also limits ramping times for any processes due to the potential of cracking of the whole wafer or the nitride film. This leads to increased reactor process times and compromises on device structures. The typical MQW is only 10s of angstroms thick. The reactor must rapidly change both process gases and temperature in order for a useful structure to be made. These rapid temperature changes will crack even thin templates, especially for 3 and 4 inch wafers. As a simple example, a flexible freestanding nitride can be heated white hot using a butane torch in a matter of seconds. Heating rates of 1000 degrees C. per second have been demonstrated using flexible freestanding nitride foils. If the same thing is done to a template, the template will shatter violently. The use of freestanding nitride veneers eliminates all these issues because they are substantially homogeneous, provide a lattice match and are flexible in nature.

Alternately, bulk nitride wafers are extremely expensive and must be surface polished which introduces surface defects. As disclosed by Dmitriev in US Pending Patent Application No. 20060280668, bulk wafers can be grown using a multiple step process that includes formation of a seed on a non-native substrate, removal of the seed form the non-native substrate, polishing and cleaning of the seed, regrowth using HVPE on the seed to form a boule with a thickness greater than 5 mm, slicing of the boule into wafers, and polishing the wafers to make an epi-ready surface. Also because the bulk nitride wafers are sliced from a bowed thick growth, a variable miscut is created when a flat wafer is made. Since growth conditions are different for various miscut angles, the result is a reduction in useable surface area on the wafer. The thick nature of bulk nitride wafers and the processing required to make them generates very high stress gradients within the wafers themselves. In contrast the flexible nitride veneers are low stress and have a uniform crystal orientation across the surface of the veneer.

Lastly, any useful device will require thinning to reduce the thermal impedance of the device. Doubling the thickness doubles the temperature delta across the layer. The same can be said for series resistance in vertical devices and optical absorption in optical devices. In all these cases, the thicker the device the layer the performance. The need therefore exists for the disclosure of devices, methods, and equipment which is specifically design to take advantage of the benefits that freestanding nitride veneers offer.

### SUMMARY OF THE INVENTION

This invention discloses the use of high temperature bonding and interconnect methods for devices based on freestanding nitride veneers. The use of inorganic glasses is a preferred embodiment of this invention. Even more preferred is the use of inorganic glasses which exhibit a CTE of between 20 and 100/C. Most preferred is the use of inorganic glasses, which exhibit a CTE, which substantially matches the CTE of the freestanding nitride devices being packaged. The use of heating means includes, but is not limited to, laser welding, brazing, ovens, kilns, torches, furnaces, and IR lamps to melt the inorganic glasses such that bonding occurs between the inorganic glasses and the freestanding nitride devices. This bonding step can adhere an electrical interconnect means to at least one surface of the freestanding nitride devices. The electrical interconnect means may consist of, but is not limited to, a wire, foil, rod, or ball. Glass sealing metals, such as Kovar, dumet, and platinum, can ensure compatibility with the inorganic glass. The ability to melt bond contacts onto the freestanding nitride devices using inorganic glasses is disclosed. In this manner contacts and/or full/or partial encapsulation of the freestanding nitride devices can be realized very rapidly. Unlike organic solutions, inorganic glasses can provide hermetic sealing of the freestanding nitride devices or at least the contact regions of the freestanding nitride devices. For LED and other optoelectronic devices the use inorganic glasses is critical to preventing solarization, yellowing, and other degradation effects that plague existing high intensity LED applications. In order for high temperature processing to be possible the LED die themselves must be capable of being processed at these high temperatures.

In the method disclosed by the authors in U.S. Pat. Nos. 7,727,790 and 8,163,582 (included by reference to this disclosure) flexible freestanding nitride veneers are harvested with an epi ready surface. By using the freestanding nitride veneer, subsequent growth can occur on an epi-ready surface, which does not require any additional polishing steps. In addition the substantially all nitride nature of this approach enables the high temperature thermal processing disclosed in this filing. By eliminating waferbonding and/or bimorphic nature of other nitride device fabrication techniques high temperature processes are made possible. The flexible nature of the freestanding nitride veneer allows for release and control of the stresses created in the nitride layer during initial growth and in subsequent high temperature processing steps. As also disclosed previously by the authors, this effect can be used to modify spectral output, current droop, as well as other device parameters. In general, the flexible freestanding nitride veneer allows the device designer some level of control over the spontaneous, piezoelectric, and induced polarization fields, which dominate nitride device performance. There are also indications that the lower surface stress in flexible freestanding nitride films enable epitaxial growth of materials with large lattice mismatches and enhanced indium incorporation compared to either template or bulk nitride wafers.

Previously disclosed by the authors are methods for rapid epitaxial growth of the nitride semiconductors based on novel reactor design and the use of freestanding nitride films. Based on this approach, typical epi growth cycle time can be reduced by up to a factor of 10. This approach uses a novel freestanding nitride veneer, which is substantially all nitride based. The intent of this invention is to disclose methods and approaches for very high speed packaging of the resulting freestanding nitride semiconductor devices. These techniques are enabled by the freestanding nature of the nitride veneer, which enables the use of high temperature glass encapsulation, rapid epi growth, novel device structures, and new interconnect means. This approach also allows for hermetically sealed devices, especially with regard to LEDs and laser diodes. The freestanding nature of the devices enables the use of these techniques in a wide range of applications ranging from illumination to 3D stacked semiconductors.

This invention also discloses the use of the freestanding nature of the nitride veneer. Freestanding nitride veneers provide access to both sides of the veneer, do not require additional thinning processes, can be laser cut, can be attached to non-flat surface, can be flexed during or after device growth, can be cleaved along polar, non-polar, and semi-polar crystal planes and can be processed at very high temperature. The use of these advantages in device structures, subsequent processing and equipment design are embodiments of this invention.

### BRIEF DESCRIPTION OF THE DRAWINGS

FIG. 1 depicts a side view of a standard prior art epoxy encapsulated LED.

FIG. 2 depicts a side view of a typical prior art white phosphor thin film LED.

FIG. 3 depicts a side view of a freestanding nitride semiconductor device with dual sided transparent contacts of the present invention.

FIG. 4 depicts a side view of a freestanding nitride semiconductor device with printed current spreading elements of the present invention.

FIG. 5 depicts a side view of a freestanding nitride LED with wire interconnects and glass encapsulation of the present invention.

FIG. 6 depicts a side view of a freestanding nitride solar cell with interconnect and collection optics of the present invention.

FIG. 7 depicts a side view of a 3 dimensional stacking of freestanding nitride devices with ball bumps and glass encapsulants of the present invention.

FIG. 8 depicts a side view of a freestanding nitride laser diode with partial encapsulation and cleaved end faces of the present invention.

FIG. 9 depicts a side view of a freestanding nitride arrays with optical micro lenses of the present invention.

FIG. 10 depicts a side view of a projector with a freestanding nitride display element with active matrix addressing elements formed on the freestanding nitride display element and color sequential element of the present invention.

FIG. 11 depicts a side view of a projector with 3 freestanding active matrix addressed display elements of the present invention.

FIG. 12 depicts a side view of a freestanding nitride device with a glass encapsulant, which contains a luminescent material of the present invention.

FIG. 13 depicts a side view of two freestanding nitride growth substrates bonded together of the present invention.

FIG. 14 depicts a perspective view of a device grown on a cleaved edge of at least one freestanding nitride growth substrate of the present invention.

FIG. 15 depicts a side view of a nitride transistor formed on cleaved edge of freestanding nitride growth substrate of the present invention.

### DETAILED DESCRIPTION OF THE INVENTION

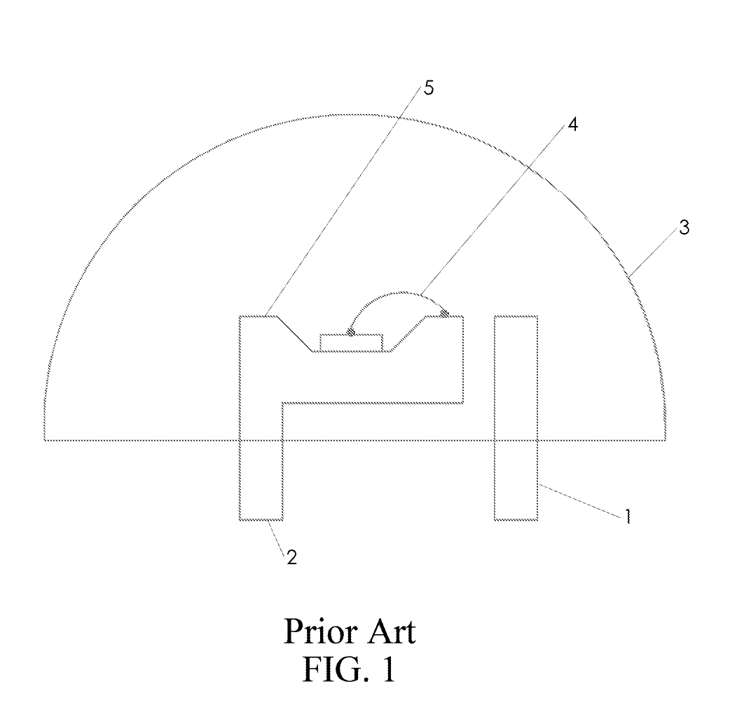

FIG. 1 depicts a standard LED. LED die 5 is typically mounted to contact pin 2 via a conductive epoxy. Wire bond 4 makes a connection between LED die 5 and contact pin 1. When a voltage is applied between contact pin 2 and contact pin 1, the LED die 5 emits light. Typically an organic encapsulant 3 surrounds the entire assembly to protect wire bond 4, environmentally protect the assembly, and improve light extraction and/or impart directionality to the emitted light from LED die 5. This approach is limited in its usage to low current applications due to the lack of thermal cooling and die size limitations. Organic encapsulants typically exhibit thermal conductivity less than 0.1 w/m/K.

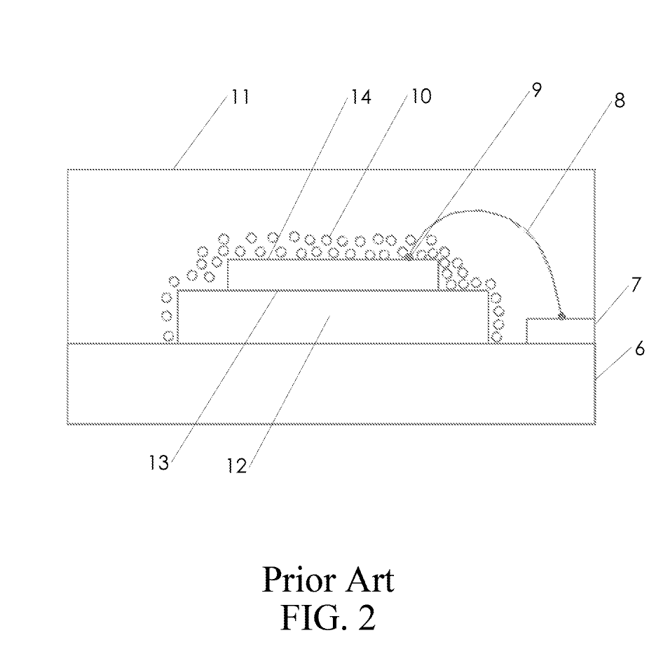

FIG. 2 depicts a typical white LED. Active region 14 is waferbonded via a solder 13 to LED substrate 12. Submount 6 provides thermal spreading and interconnect means for the assembly. Heat generation is localized in active region 14 and propagates through solder 13 through LED substrate 12 which is attached via a variety of means known in the art to submount 6. The overall thermal impedance of the device is defined not only by the bulk conductivity of the various layers but also by the interfaces required to bond the layers together. This is especially important in high powered applications. A vertical structure is shown in FIG. 2, which requires wirebond 8 between the top contact 9 and submount contact 7. Powder phosphor 10 is deposited over this assembly via a number of methods. Encapsulant 11 is then used to protect the entire assembly. Vertical and flipchip mounting configurations are typically used but all suffer from the same high thermal impedance and complex interconnect issues. Both devices shown in FIG. 1 and FIG. 2 are unsuitable for general lighting applications due to cost and performance limitations. FIG. 1 devices typically emit only a few lumens of output due to thermal limitations. FIG. 2 devices can emit more lumens but cost 10 to 100 times more than incandescent and fluorescent lighting. In addition, both the encapsulant 11 and phosphor powder 10 are unstable from a life and color stability standpoint. The need exists for lower cost, thermally and environmentally stable approaches for solid state lighting.

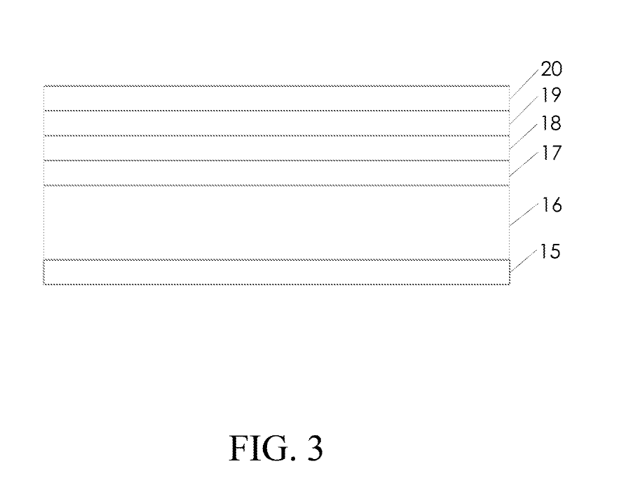

FIG. 3 depicts a freestanding nitride semiconductor. Freestanding nitride layer 16 is typically between 10 and 200 microns thick. More preferably freestanding nitride layer 16 is between 20 and 100 microns thick and, even more preferably, freestanding nitride layer 16 is between 30 and 80 microns thick. The thickness of the freestanding nitride layer 16 allows for flexibility, low thermal impedance, and high crystal quality. As known in the art, HVPE can be used to grow reasonably thick nitride layers on a substrate typically sapphire. As previously disclosed by the authors, laser liftoff can be used to separate large areas of the nitride layer from the sapphire forming a freestanding nitride layer 16. Alternately, photochemical etching, chemical etching, weak interface and mechanical means can be used to remove the non-native growth substrate. Using the method previously disclosed by the authors, 30 micron thick nitride layers over 1 inch square in area have been created. These layers are both transparent in the visible region and flexible.

This invention covers methods and devices based on using freestanding nitride layer 16 as an epitaxial growth substrate. By using freestanding nitride layer 16 as the growth substrate for subsequent epitaxial growths, improved device performance is possible. In the cases where the sapphire is still attached to nitride layer, significant stresses are always present. This is due to the lattice and thermal mismatches that always exist between the growth substrate and the epitaxially grown layer. This is based on effects of the strain on the quantum wells and various other layers. Active region 17 in this case is grown on freestanding nitride layer 16. Because freestanding nitride layer 16 does not required additional polishing and is flexible in nature the growth quality of the active region 17 can be improved. In addition the flexible nature of the freestanding nitride layer 16 allows for modification of the spontaneous, piezoelectric and induced polarization fields in the device being grown. Active region 17 typically consists of, but is not limited to, a PN junction, MOSFET, MESFET, HEMT, single or double heterojunction, and/or quantum wells or dots layers. Active region 17 may function as a LED, laser diode, solar cell, diode, HEMT, FET, as well as other electronic and optoelectronic devices. InGaN, InAlGaN, AlGaN, or other dilute nitride alloys are used to create the active region in the case of LEDs. By epitaxially growing on a freestanding nitride layer 16, the stresses within the active region 17 can be reduced. Not only does the freestanding nitride layer 16 provide a better lattice and thermal match for the active region 17 but freestanding nitride layer 16 also typically exhibits less dislocation defects than thin template based approaches.

Contact layer 15 may consist of but not limited to transparent conductive oxides, nitrides, and other high temperature coatings. More preferably contact layer 15 is an epitaxially grown transparent conductive oxide. Most preferably contact layer 15 is doped zinc oxide. The contact layer 15 protects the backside of freestanding nitride layer 16 during subsequent growth processes. The contact layer 15 simultaneously serves as current spreading layer for the device and protects the freestanding nitride layer 16 during subsequent growth processes. Contact layer 15 consists of and/or contains a luminescent element.

The contact layer 15 may be patterned to be used as a etch mask for the freestanding nitride layer 16. The use of sequential depositions for contact layer 15 allows that contact layer 15 to consist of substantially different materials spatially distributed across freestanding nitride layer 16. The formation of color pixels based on sequential depositions of contact layer 15 on freestanding nitride layer 16 is also disclosed. It is an embodiment of this invention the use of high temperature processing in excess of 1000 degrees C. for freestanding nitride layer 16 and contact layer 15. This enables the formation of high quality luminescent materials and/or contact layers, which can not be done due to temperature limitation of active layer 17. Active region 17 cannot be processed at temperatures much above 1000 degrees C. due to diffusional effects and stability of the nitride alloys typically used. It is therefore an embodiment of this invention that contact layer 15 and freestanding nitride layer 16 can be processed at temperature greater than 1000 degrees C.

Luminescent properties in particular can be enhanced/activated only through the use of high temperature annealing in controlled atmospheres. As such the use of annealing steps to enhance luminescent properties of Contact layer 15 on freestanding nitride layer 16 within a controlled atmosphere prior to subsequent epitaxial growths is an embodiment of this invention. The annealed contact layer 15 and freestanding nitride layer 16 which is luminescent is an embodiment of this invention. The luminescent contact layer 15 and freestanding nitride layer 16 can be used as a growth substrate for making a light emitting device. The formation of the active region 17 after the formation of the luminescent contact layer 15 is an embodiment of this invention. In this manner, high temperature processing of the luminescent material can be done without degrading the LED or other optoelectronic device.

Similarly, it has been previously disclosed by the authors that the use of freestanding nitride layer 16 enables high temperature device formation followed by lower temperature device formation for solar cell and electronic applications. In general, the freestanding nitride layer 16 can be used as a both a high temperature nitride growth substrate and a subsequent low temperature growth substrate either on the same side as the high temperature growth substrate or the other side of the high temperature growth substrate. As an example, high quality nitride solar cells can be grown on freestanding nitride layer 16 followed by lower temperature silicon, GaAs, as well as other low bandgap materials. The resulting integrated multi junction solar cell does not suffer from the process constraints of nitride on silicon approaches where the nitride device growth adversely affects the underlying silicon devices.

Vias can be formed by etching, laser ablation, mechanical means, as well as cutting means, to enable interconnects between devices grown on different sides of freestanding nitride layer 16. Subwavelength structures cane be formed including, but not limited to quantum dots, gratings, diffusers, and polarization elements, on either and/or both sides of contact layer 15 and freestanding nitride layer 16 prior to subsequent growth processes. Addressing elements can be formed on or within contact layer 15.

Freestanding nitride layer 16 may consist of n type, p type, and/or semi-insulating material. Freestanding nitride layer 16 maybe uniformly doped, gradient doped, and stepwise doped. The annealing processes on freestanding nitride layer 16 reduce bowing, improve doping uniformity, and modify surface morphology. The formation of surface texture using but not limited to laser patterning, lithography, chemical etching, and/or mechanical means as known in the art to improve extraction efficiency, enhances epitaxial growth (e.g. lateral overgrowth etc.) and/or modifies the stresses in nitride layer 16. Using these techniques an enhanced growth substrate is disclosed. Subsequent growth steps including active region 17, barrier layer 18, and doped layer 19 are used to form the desired device.

Because the growth substrate is substantially an all nitride layer 16, flexible very rapid thermal processing can be used to improve the interfaces between the subsequent growth layers. This becomes critical especially in the cases where quantum wells are being formed. The various layers must exhibit significant changes in composition in layers, which are only a few nanometers thick. This requires rapid changes in the growth conditions at the epitaxial surface. In the case of nitrides, growth temperatures determine the composition of the layers. As an example, 20% indium content InGaN requires a much lower growth temperature than GaN. Since MQWs typically consist of alternating layers of various nitride alloys 100s of degrees C. temperature shifts must occur in seconds. The combination of low thermal mass, thinness, and high thermal conductivity enables freestanding nitride layer 16 with or without contact layer 15 enables the formation of improved device structures. The use of nitride layer 16 with or without contact layer 15 as an enhanced growth substrate to allow for more rapid changes in growth conditions is an embodiment of this invention. Most preferred is a freestanding nitride layer 16 with or without contact layer 15, which is less than 100 microns thick. Even more preferred is a freestanding nitride layer 16 with or without contact layer 15, which is less than 50 microns thick.

Contact layer 20 consists of but is not limited to, transparent conductive oxide, luminescent layer, and/or active addressing element. The use of degenerative doping levels in one or both contact layers 15 and 20 is also an embodiment of this invention. The epitaxial growth methods forms contact layer 15 and 20 for reduced alpha. The epitaxial growth of contact layer 15 and 20 via MOCVD either separately or simultaneously is also an embodiment of this invention. Mechanical, laser, etching and waterjet means can scribe, cut and/or break the freestanding nitride semiconductor layer into smaller devices. More preferably, the cleaving along cleave planes can form triangular and/or triangular based shapes.

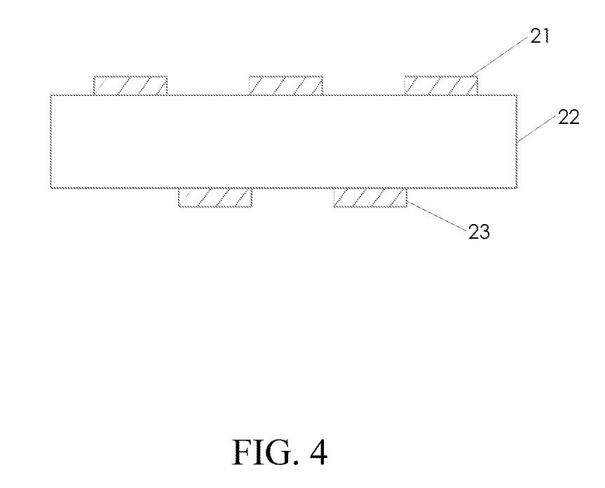

FIG. 4 depicts a freestanding nitride device 22 with printed traces 21 and 23. The high temperature nature of the nitride 22 allows for the use of thick film processes, which require at least rapid temperature excursions in excess of 500 degrees C. The substantially homogeneous nature of the nitride device allows for these rapid temperature processes without cracking, as is typically the case for nitrides on a growth substrate. Alternately, a waferbonded device cannot be processed at elevated temperatures because of the solder layer described previously. The flexible nature of freestanding nitride device 22 also enables the use of printing process because the freestanding nitride device 22 can be conformed to a surface via vacuum, mechanical means, and/or pressure plates. This enables the printing of high resolution features at a fraction of the cost of lithographic methods. The printing of contacts on both sides of freestanding nitride device 22 such the contacts do not substantially overlap each other is a preferred embodiment of this invention. In this manner LEDs, solar cells as well as other optoelectronics can be constructed with a minimal amount of blockage both for light entering or leaving the device. This approach can create isotropically radiative or absorbing optoelectronic devices. As discussed previously, alternately, degenerative contact layers can be used to further improve the ohmic contact between the freestanding nitride device 22 and printed traces 21 and 23. Printed traces 21 and/or 23, both conductive and semiconductive, can be formed on freestanding nitride and curing/sintering at temperatures in excess of 500 degrees C. Addressing elements can be included into and/or adjacent to printed traces 21 and 23 to form an active matrix addressable array.

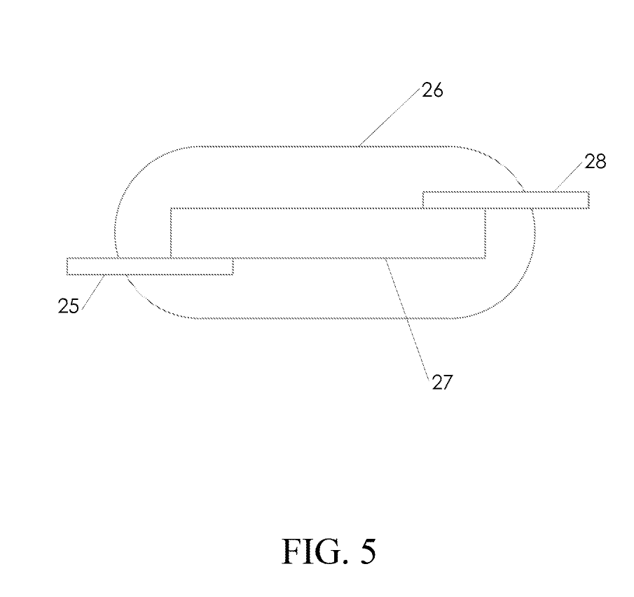

FIG. 5 depicts a glass encapsulated freestanding nitride semiconducting device 27 with wire leads 24 and 25. Glass encapsulant 26 serves as hermetic seal, mechanical support, and thermal conduction path. The use of glass encapsulant 26 exhibiting a CTE less than 100×10(−7) IC is an embodiment. More preferred is a clear glass encapsulant 26 exhibiting a CTE less than 70×10(−7)/C. Even more preferred is a glass encapsulant 25 with contains a luminescent element. Most preferred is a glass encapsulant 25, which contains a luminescent material, which exhibits a CTE that substantially matches the CTE of the freestanding nitride semiconductor device 27. Alternately, thermally conductive fillers can include, but are not limited to, graphite fibers, carbon nanotubes, diamond, boron nitride, beryllium oxide, aluminum nitride, metals, silicon carbide, and other thermally conductive materials within glass encapsulant 25 for both enhanced thermal conduction and/or CTE matching. The interconnection of multiple freestanding nitride semiconducting devices 27 within glass encapsulant 25 is also disclosed. In particular the interconnect of multiple freestanding nitride semiconducting devices 27 such that a large surface device is formed to spread out heat is disclosed.

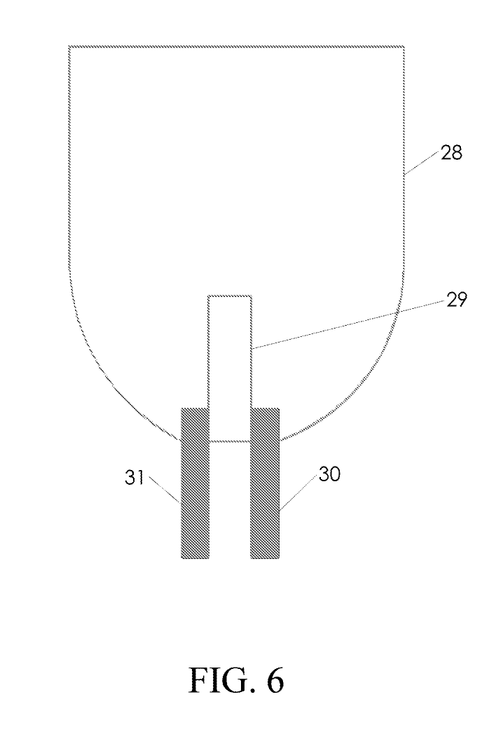

FIG. 6 depicts at least one nitride solar cell 29 contained within a collection optic 28. Collection optic 28 may consist of, but is not limited to, CPC, trough collector, and/or lens. More preferably the solid CPC is used as the collection optic 28 in which at least one nitride solar cell 29 is embedded. The collection optic 28 may also serve as a thermal cooling means. Contacts 31 and 30 may also provide thermal conduction cooling as well. The use of at least one multi-junction solar cells previously discussed within collection optic 28 is a preferred embodiment of this invention.

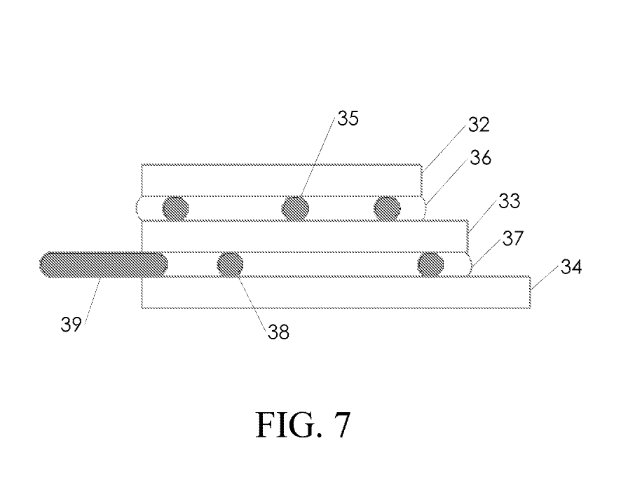

FIG. 7 depicts a 3 D electronic circuit consisting of at least one freestanding nitride devices 32, 33 and/or 34. Interconnect between at least one freestanding nitride devices 32, 33, and/or 34 is accomplished via bumps 35. Attachment and bonding of the at least one freestanding nitride devices 32, 33 and/or 34 is accomplished via glass bonding layer 36 and/or 37. The pins 39 are incorporated into the glass bonding layer 36 and/or 37. In this manner, device to device and device to external elements can be accomplished. The use of low CTE bumps 35 and pins 39, which substantially match the CTE of glass bonding layer 36 and/or 37, including, but not limited to, carbon fiber, platinum, kovar, dumet, and other low expansion metal alloys is disclosed.

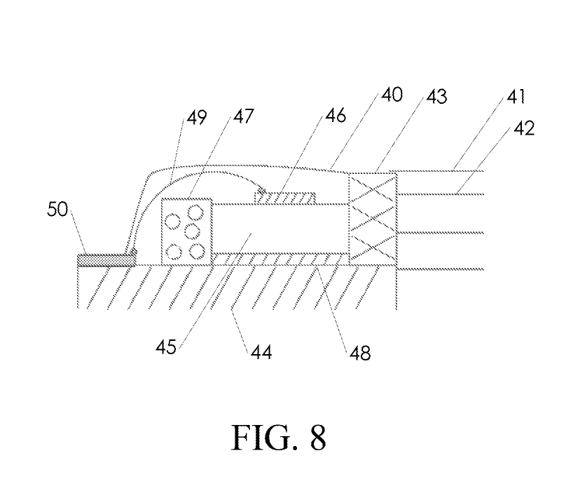

FIG. 8 depicts a nitride laser diode 45 formed using a freestanding nitride growth substrate. The freestanding nitride growth substrate allows for cleavage of input and output surfaces of nitride laser diode 45. A low thermal impedance path to heatsink 44 can be created using bonding layer 48. Rear mirror 49 can be attached to the cleaved surface of nitride laser diode 45. Electrical contact for the device is via top contact 46, wirebond 49, and contact 50 along with bonding layer 48 and heatsink 44. The overall device is protected by glass encapsulation 40 and the device can be coupled into the core 42 of glass fiber 41. An index matching gel 43 is also disclosed to reduce back reflections and increase coupling into the core 42 of fiber 41. The advantage of this approach is cleavability, low thermal impedance and the ability to reduce the stress in the active region of the laser diode 45. In particular, the freestanding nitride growth substrates with some indium content can reduce lattice mismatch with the InGaN active region for green laser diodes. The use of lateral overgrowth and non C plane growth axis on the freestanding nitride growth substrate can reduce stress and dislocations. The stacking of multiple laser diode 45 devices can form arrays of devices.

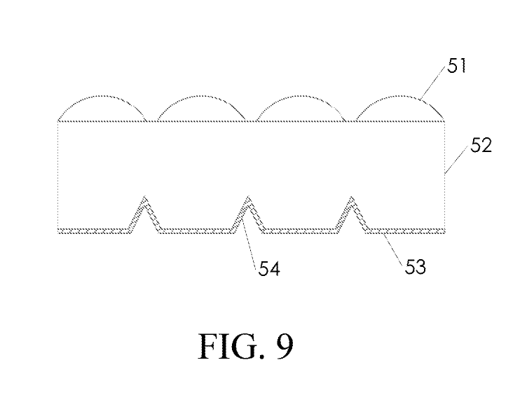

FIG. 9 depicts the formation of microoptical elements 51 substantially aligned to an array of LEDs in a freestanding nitride veneer 52. The individual LED elements are isolated via trench 54, which is formed in freestanding nitride veneer 52 via chemical etching, laser cutting, photochemical etching and/or mechanical means. The use of reflective contact 53 not only directs the emitted light from the LEDs forward but also partially collimates the output based on reflections of the sides of the trench 54. Glass molding processes form the microoptical elements 54. The use of high temperature bonding is enabled by the high temperature capability of the freestanding nitride veneer 52.

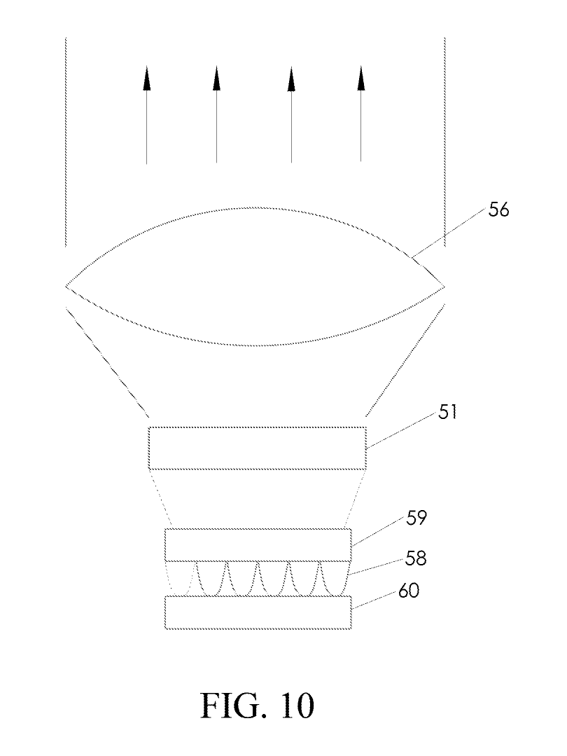

FIG. 10 depicts a projector based on freestanding nitride veneer 58 containing an array of LEDs addressed via active matrix 60. Wavelength conversion layer 59 is used to create a white spectrum output from the LED arrays. The dichroic films limit output angular distribution as previously disclosed by the authors. Wavelength conversion layer 59 contains sufficient spectral content to render an acceptable RBG color gamut when filtered using color selector 57. Color selector may consist of, but is not limited to, color filter wheel and/or color ferroelectric cell. In this manner, color sequential operation can be created leading to a single panel full color projector with minimal components. The output 55 of the projector can be imaged onto the screen via projection lens 56. The use of reflective optical elements is also disclosed.

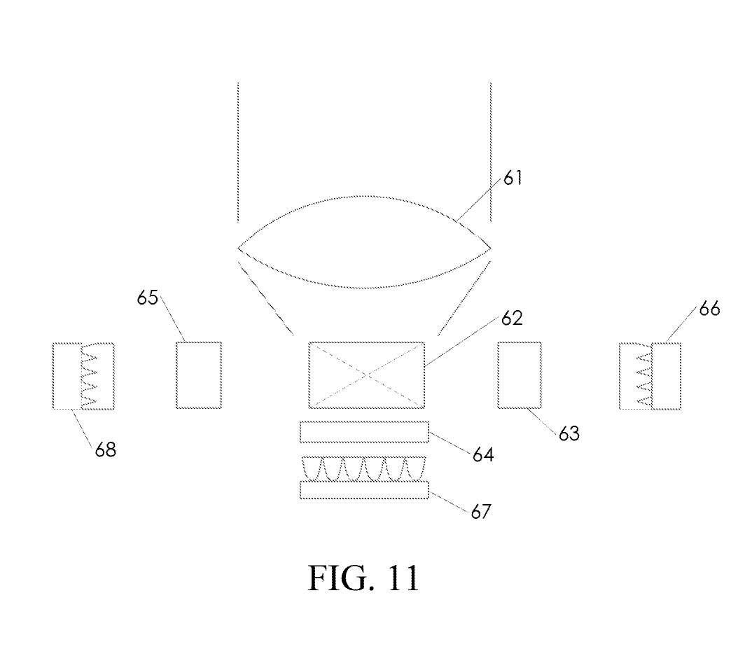

FIG. 11 depicts a three panel projector system based on three LED arrays 66, 67, and 68. Coupling optics 65, 63, and 64 serve to couple the output of the LED arrays into Xcube combiner 62, which combines the three color images. The output of x cube combiner 62 is then imaged on the screen using projection lens 61.

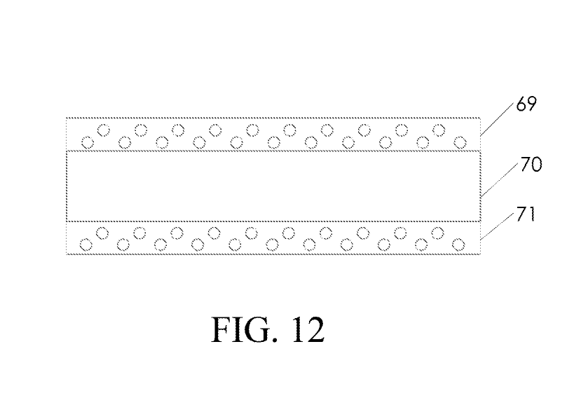

FIG. 12 depicts a freestanding nitride veneer 70 to which at least one side is coated/encapsulated with a glass matrix containing a luminescent material 69 and 71. The luminescent material may consist of, but is not limited to, powdered phosphors, solid ceramic flakes, quantum dots and combinations of each. The ability to heat the freestanding nitride veneer 70 to temperatures over 1000 degrees C. enables formation of inorganic glass layers.

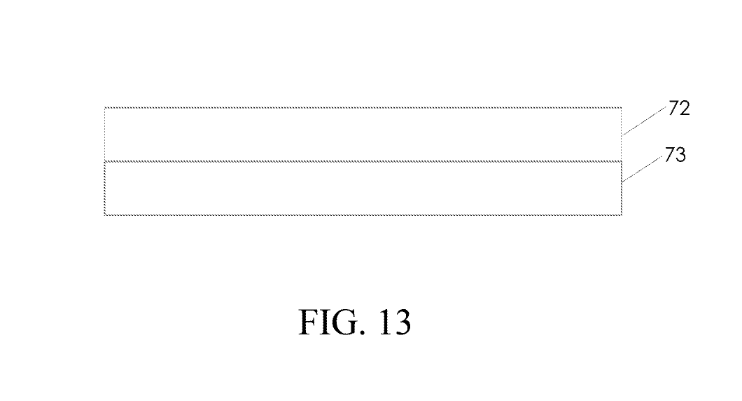

FIG. 13 depicts at least two freestanding nitride veneers 72 and 73. The surface quality and high temperature nature of at least two freestanding nitride veneers 72 and 73 enable wafer bonding. Both symmetric and asymmetric layers are disclosed. The orientation of crystal planes enhances mechanical properties, inhibits cleavage, enhances cleavage, and improves lattice mismatch issues.

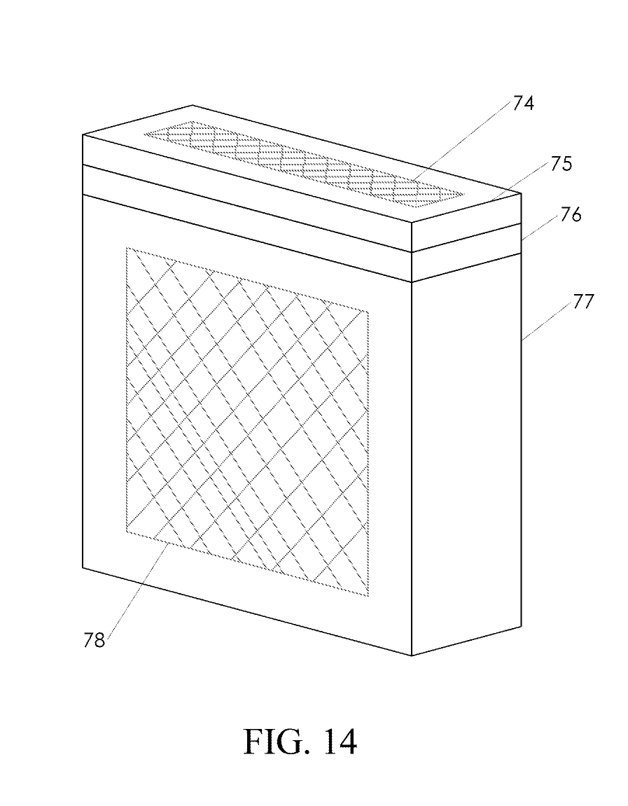

FIG. 14 depicts laser diode formed on a cleaved edge of freestanding nitride veneer 77. The electrodes 78 and 74 are placed on different crystal planes. Active region 76 and buffer layer 75 create a laser diode as known in the art. More preferably the electrodes 78 and 74 are substantially orthogonal to each other.

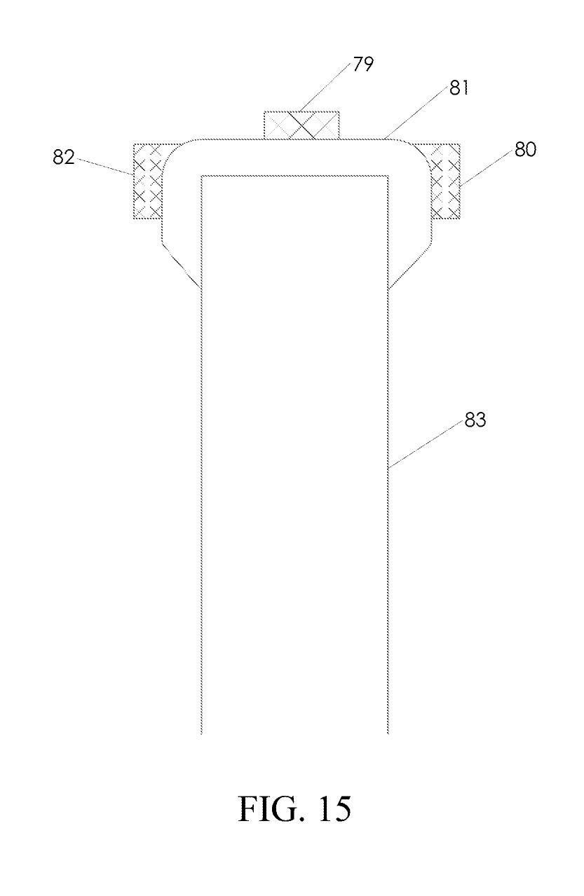

FIG. 15 depicts a nitride transistor formed on a cleaved edge of freestanding nitride growth substrate 83. Drain 82 and Source 80 are formed substantially on the side of freestanding nitride growth substrate 83 and active layer 81. 2 DEG is formed at the interface between freestanding nitride growth substrate 83 and active layer 81. The current flow is controlled via voltage applied to Gate 79. The advantage of this approach is the use of a cleaved edge, which can optionally be substantially aligned to a non-polar or semi-polar crystal plane. This can reduce the effects of spontaneous and piezoelectric polarization field within the device. The physical placement of the Drain 82 and Source 80 can also enhance device performance by reducing surface electron losses. Alternately, freestanding nitride growth substrate 83 serves as a gate either by itself or in conjunction with gate 79. The use of barrier layers, recessed gates, and other structures, which enhance devices performance as known in the art are included as embodiments of this invention.

While the invention has been described in conjunction with specific embodiments and examples, it is evident to those skilled in the art that many alternatives, modifications and variations will be apparent in light of the foregoing description. Accordingly, the invention is intended to embrace all such alternatives, modifications and variations as fall within the spirit and scope of the appended claims.

1. A freestanding nitride semiconductor device with transparent electrical contacts on at least two surfaces of said freestanding nitride semiconductor device.

2. The freestanding nitride semiconductor device of claim 1 with at least one additional printed current spreading element.

3. A three dimensional stack of freestanding nitride devices interconnected via ball bumps.

4. The three dimensional stack of freestanding nitride devices of claim 3 wherein said stack is embedded within glass.
